(19) United States
(12) Patent Application Publication
(10) Pub. No.: US 2003/0101410 A1
(43) Pub. Date: May 29, 2003

(54) Method and apparatus for detecting and correcting errors in a magnetic recording channel of a mass storage system

(75) Inventors: Giorgio Betti, Pogliano Milanese (IT); Filippo Brenna, Villa Raverio (IT); Angelo Dati, Viareggio (IT); Augusto Rossi, San Diego, CA (US); Luca Reggiani, Ferrara (IT)

Correspondence Address: SEED INTELLECTUAL PROPERTY LAW GROUP PLLC, 701 FIFTH AVE, SUITE 6300, SEATTLE, WA, 98104-7092, US

(73) Assignee: STMicroelectronics S.r.I, Agrate Brianza (IT)

(21) Appl. No.: 10/176,968

(22) Filed: Jun. 21, 2002

(30) Foreign Application Priority Data
Jun. 22, 2001 (EP) 01830422.0

(51) Int. Cl. H03M 13/00; H03M 13/03

(52) U.S. Cl. 714/794

(57) ABSTRACT

A method and apparatus for detecting and correcting errors in a magnetic recording channel of a mass storage system that combines a Soft Output Viterbi Algorithm SOVA, which has the capability of detecting the reliability of a discrete, equalized signal, and a post processor, which has the capability of detecting specific error events in said discrete, equalized signal, so as to correct error events and to generate an output bit stream.

### BACKGROUND OF THE INVENTION

1. Field of the Invention

The present invention relates to a method and apparatus for detecting and correcting errors in a magnetic recording channel of a mass storage system, particularly, but non exclusively, for detecting and correcting errors in a magnetic recording channel of a hard disk drive (HDD).

2. Description of the Related Art

As computer hardware and software technology continue to progress, the need for larger and faster mass storage devices continues to increase.

To meet these ever increasing demands, hard disk drives (HDDs) continue to evolve and advance.

A HDD performs write and read operations when storing and retrieving data. A typical HDD performs a write operation by transferring data from a host interface to its control circuitry.

A model of a prior art digital communication system is illustrated in FIG. 1. Information source 8 generates either analog or discrete information which the source encoder 9 encodes into an information sequence x. A channel encoder 10 transforms the information sequence x into a new sequence x′ by means of a process known as channel encoding. A modulator 11 uses the encoded output to generate channel signals for transmission over a transmission channel 12.

In general, the transmission channel 12 exhibits noise and other impairments, for example frequency and phase distortion and a variety of fading characteristics. A digital demodulator 13 demodulates the transmitted signal to produce an estimate of the encoded information sequence x′. A channel decoder 14 then takes this estimate and attempts to reproduce the information sequence. Finally, a source decoder 15 transforms the reconstructed information sequence x′ into a form suitable for an information destination 16.

The channel encoding 10 is a means to efficiently introduce redundancy into a sequence of data and to promote the reliability of the transmissions.

There are some ways in which the redundant information may be used to improve the accuracy or the reliability of the received information, such as, for example, the error detection, wherein the decoder determines only whether the received sequence is correct or if errors have occurred, or such as the error correction, wherein the decoder uses the redundant information to both detect and correct errors in the received sequence, or such as the automatic request, wherein the detection of an error will automatically initiate a request of repeat data.

Particularly, an error correction code, such as Reed-Solomon code, is able to detect the wrong bytes and to correct them. Moreover such a code adds to the transmitting data a few bytes of redundancy. In fact with “2t” bytes of redundancy it is possible to correct until “t” wrong bytes.

Moreover to the error correction code, a code of cyclic redundancy check type (CRC) is added, which enables verification of the consistency of data, because the Reed-Solomon code can sometimes make wrong corrections.

The channel code, instead, can introduce an appropriate modulation, in function of the used transmission channel.

Usually the channel decoder 14 implements the so-called Viterbi Algorithm. The Viterbi Algorithm is a well-known method for decoding convolutional codes. In fact the Viterbi Algorithm is the optimum decoding algorithm in the sense of maximum likelihood estimation for a convolutionally encoded sequence transmitted over a memoryless channel, such as the channel shown in FIG. 1.

The basic theoretical concept of the Viterbi Algorithm can be described as correlating all possible transmitted code sequences with the received sequence and then choosing as the “survivor” the sequence where the correlation is maximum, i.e., the path with the best “metric”.

FIG. 2 is a block diagram of a hard disk drive mass storage system 1 used for retrieving data during read operations and for storing data during write operations. Hard disk drive mass storage system 1 interfaces and exchanges data with a host 2 during read and write operations. Hard disk drive mass storage system 1 includes a disk-head assembly 3, a preamplifier 4, a synchronous data sampler 5 and a control circuitry 6.

The disk-head assembly 3 and the preamplifier 4 are used to magnetically store data. The synchronous data sampler 5 and the control circuitry 6 are used to process data that is being read from and written to the disk-head assembly 3 and to control the various operations of the hard disk drive mass storage system 1. Host 2 exchanges digital data with control circuitry 6.

Synchronous data sampler 5 is used during read and write operations to exchange analog data signals with disk-head assembly 3 through preamplifier 4 and to exchange digital data signals with control circuitry 6 through a data-parameter path 7.

In the read-write channels of the HDD, for example, the channel code is studied in a way to allow the exclusion of particular error events, and to improve in this way the Bit Error Rate (BER) of the hard disk drive mass storage system 1. The error events are wrong sequences that statistically tend to repeat themselves, due to the same condition of the Signal to Noise Ratio (SNR).

For the read-write channel of the hard disk drive mass storage system 1, for example, the error events more relevant, for medium-low values of the SNR, are listed in the following table 1:

| Transmission | | |
|---|---|---|
| Sequence | Received Sequence | Error Events |
| . . . x x 1 x x . . . | . . . x 0 x x . . . | + |
| . . . x 1 0 1 x . . . | . . . x 0 1 0 x . . . | + − + |
| . . . x x 1 0 x x . . . | . . . x x 0 1 x x . . . | + − |

As shown in the table 1, the error event more common is that wherein a single bit is not correct.

A simple way to reduce the number of the committed errors during a reading operation of stored information consists in the use of a parity channel code, wherein to each digital word of the code is added a bit, the value of which is so as to make even the number of ones, belonging to said digital word.

### BRIEF SUMMARY OF THE INVENTION

The disclosed embodiments of the present invention increase the efficiency of the detector of a recording channel of a mass storage system.

According to the embodiments of the invention, a method for detecting and correcting errors in a sequence of signals is provided. The method includes the steps of a) receiving said signals over a communication channel corrupted by noise; b) transforming said signals into discrete signals equalized to a predetermined target function; c) computing a bit stream and the associated reliability of said discrete signals; d) postprocessing said bit stream and said reliability in function of said discrete signals to detect specific error events; e) making correction of said error events by filtering each single error event; f) generating an output bit stream.

According to another embodiment of the present invention, an apparatus for detecting and correcting errors in a magnetic recording channel of a mass storage system is provided. The apparatus includes a block implementing a Soft Output Viterbi Algorithm operable to receive a discrete equalized signal and to generate a bit stream and to associate a reliability to said bit stream; a delay line operable to receive said discrete equalized signal and to generate a delayed version of said discrete equalized signal; a post processor operable to receive said bit stream, said associated reliability and said delay version of said discrete equalized signal, said post processor operable to generate a first signal; an error correction block operable to receive said first signal and operable to generate an output bit stream.

As will be appreciated from the foregoing, it is possible to combine a SOVA detector and a post processor so to make full use of the characteristics of the parity channel code.

### BRIEF DESCRIPTION OF THE SEVERAL VIEWS OF THE DRAWING(S)

The features and the advantages of the embodiments of the present invention will be made evident by the following detailed description of a few of its particular embodiments, illustrated as a non-limiting example in the annexed drawings, wherein:

FIG. 1 shows a schematic block diagram of a digital communication system according to the prior art;

FIG. 2 shows a block diagram illustrating a hard disk drive mass storage system according to the prior art;

FIG. 3 shows a block diagram of a read-write channel according to the prior art;

FIG. 4 shows a state machine and a correspondent trellis according to the prior art;

FIG. 5 shows a block diagram of a post processor according to the prior art;

FIG. 6 shows a block diagram of a combination between a SOVA detector and a post processor according to the present invention;

FIG. 7A shows an error identification on a bit stream according to the present invention;

FIG. 7B shows an error correction on the same bit stream of FIG. 7a according to the present invention;

FIG. 8 shows another block diagram of a combination between a SOVA detector and a post processor according to the present invention;

FIG. 9 shows a table of a data sector of a device of FIG. 8 according to the present invention;

FIG. 10 shows a flow chart of a method according to the present invention.

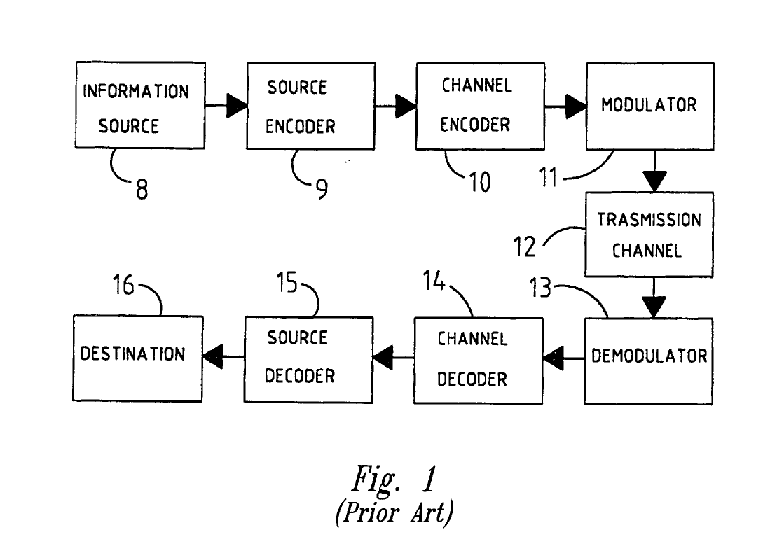

### DETAILED DESCRIPTION OF THE INVENTION

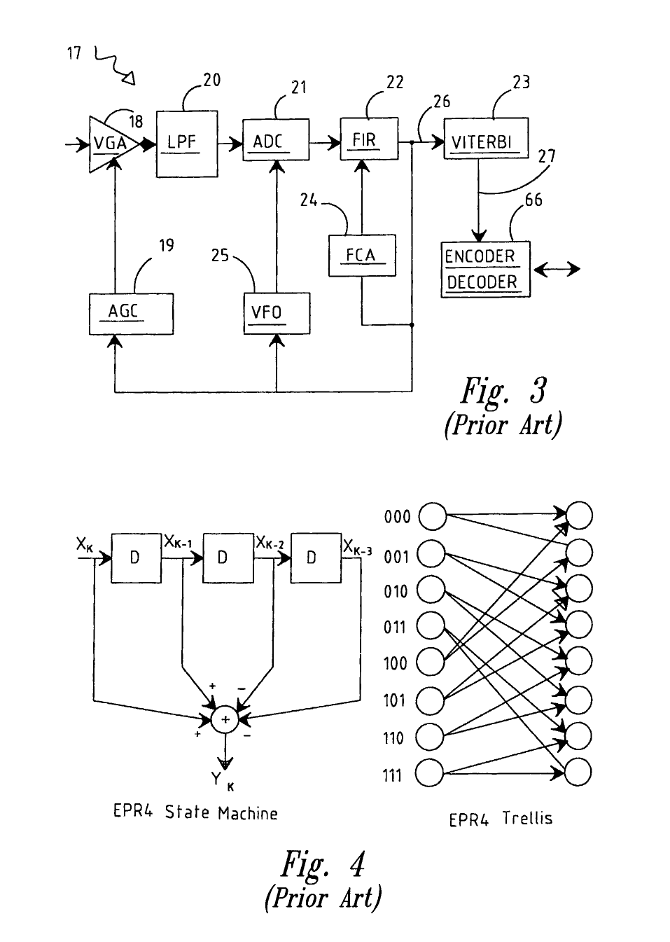

FIG. 3 is a block diagram of a read-write channel according to the prior art.

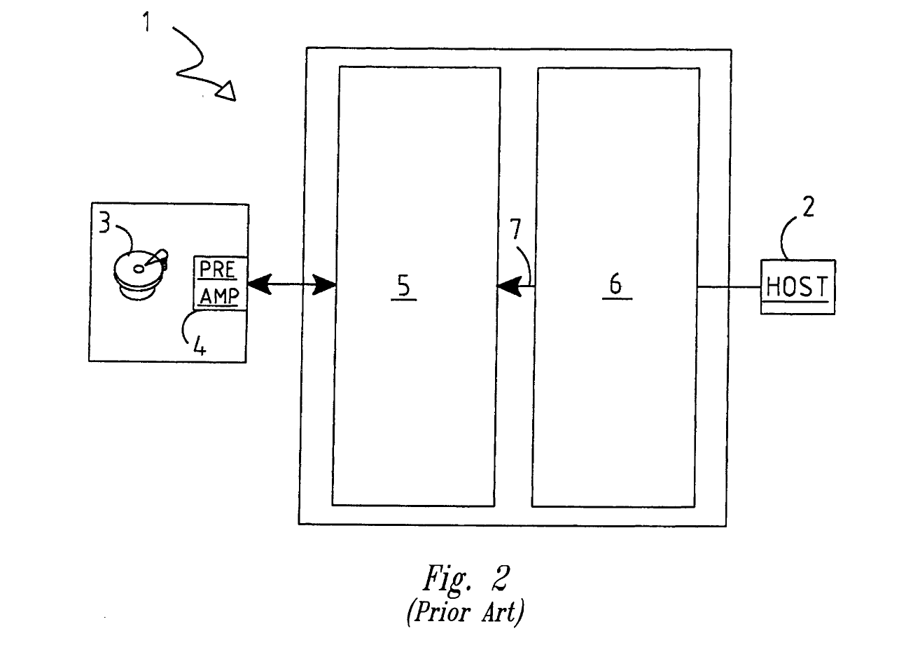

Referring back to FIG. 2, it is to be noted that the synchronous data sampler 5 includes besides other devices a read-write channel 17 that is depicted in FIG. 3.

The read-write channel 17 is composed by a variety of circuit modules used to process and condition an analog signal received from the preamplifier 4 and the disk-head assembly 3. The circuit modules of the read-write channel 17 include a variable gain amplifier (VGA) 18, an automatic gain control (AGC) 19, a low pass filter (LPF) 20, an analog to digital converter (ADC) 21, a finite response filter (FIR) 22, a Viterbi detector 23, a filter coefficients adaptation (FCA) 24, a variable frequency oscillator (VFO) 25 and an encoder-decoder circuit 66.

All these circuit modules are used during read-write operation to perform various functions and to condition the analog read signal so that the corresponding digital data signal is provided to the control circuitry 6 and ultimately to the host 2.

To optimize the equalization, the impulsive answer of the channel 17 is modeled so as to correspond to a predefined sequence, that is usually indicated as “target”. To every target corresponds a finite state machine, that describes the ideal outputs of the channel 17 to every state and to every input.

For example, as FIG. 4 shows, if the read-write channel 17 is implemented as a partial response, class IV (EPR4), the algorithm implemented in the Viterbi detector 23 uses the same state machine. In fact FIG. 4 shows the state machine corresponding to the target EPR4 and the corresponding trellis, which describes the evolution of the state machine in the time.

Moreover, the polynomial implemented in the FIG. 4, as a target of the operation of equalization, is a polynomial of the third order, such as:

P(D)=1+D−D²−D³ (1)

Therefore the corresponding state machine will evolve through eight states.

Particularly, referring again to FIG. 3, the Viterbi detector 23 receives a discrete equalized signal 26 from the FIR 22 and the Viterbi detector 23 analyzes said signal 26 to produce an output digital data signal 27 corresponding to the data stored on the disk-head assembly 3.

So-called hard or soft decision schemes may be employed to determine the best path trough the trellis. In a hard decision scheme, the metric may be defined as the Hamming distance between the received digital word and the outputs. In a soft decision scheme, also called Soft Output Viterbi Algorithm (SOVA), the Hamming metric is replaced by a soft decision metric, such as, for example, the computing of the likelihood of the candidate paths given knowledge of the probability distribution of the received signal 26 at the Viterbi detector 23.

Moreover, the position of the all bytes or only the position of some bytes is known, it is possible to improve the correction capability and therefore to reconstruct correctly the data.

If the Viterbi detector 23 is a SOVA type, in the presence of uncorrectable wrong transmissions, it is possible to implement an iterative strategy consisting in the selection of one or more bytes that have reliability values less than a predetermined threshold.

At this point, with fixed one or more error positions, called erasures, the correction capability increases.

However the information quality provided by the SOVA detector 23, and therefore the capability of the system to identify the possible wrong bytes, decreases at the decreasing of the Signal to Noise Ratio (SNR).

Moreover, it is possible, assuming that to the “k” user bytes are added “2 t” redundancy bytes, to correct until “t” errors by means of the Reed-Solomon detector, supposing that it is not known the position of the wrong bytes.

However, if the wrong bytes are “t+1”, it is not possible to reconstruct the transmitted user bytes.

It is to be noted, further, due to the elevated date rate requested in the modern HDD (more than 700 Mbit/sec), the solutions wherein some characteristics of the channel code are enclosed in the Viterbi detector 23 may limit heavily the data rate.

Therefore, as it is known to a skilled person, a block that makes a post processing suitable to the decisions of the Viterbi detector can be added to the Viterbi detector.

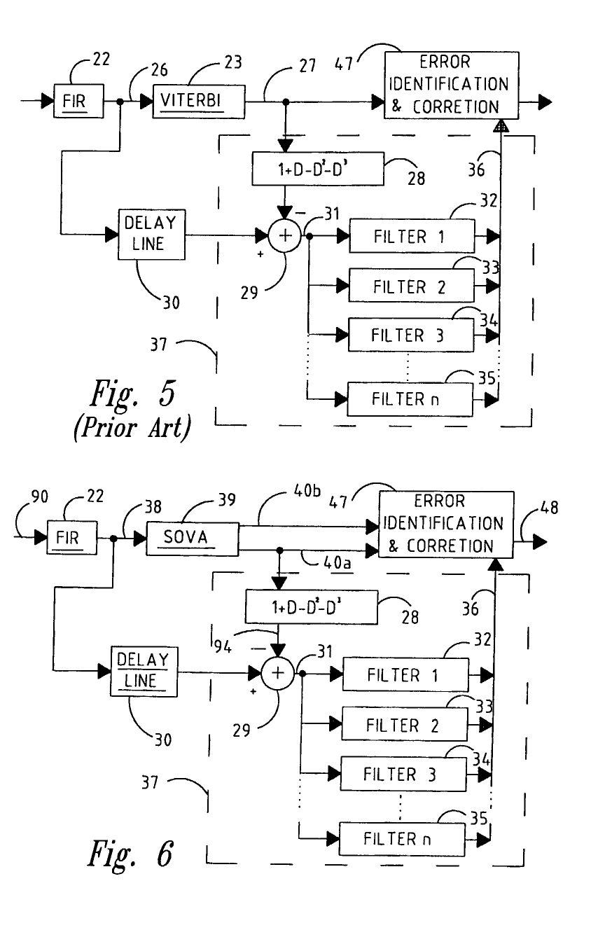

FIG. 5 shows a such an architecture, wherein the hard outputs of the Viterbi detector 23 are filtered by means of a post processor 37, that particularly includes an identical polynomial P(D), used for the equalization operation, and a group of filters 32, . . . , 35.

In this specific embodiment a target EPR4 is used and therefore the polynomial 28 is again:

P(D)=1+D−D²−D³ (2)

By means of the adder node 29 the output samples 28 are subtracted to real output samples of the FIR 22, and these are delayed by means of a delay line 30.

In this way, the output signal 31 of the adder node 29, in absence of errors by Viterbi detector 23, is a pure white noise.

If the Viterbi detector 23 makes a wrong decision, the output signal 31 will have special characteristics that are a function of the error event.

The group of filters 32, . . . , 35 is tuned in a specific error event to recognize which error event is occurring in said output signal 31 and where in the bit stream.

The deduced data 36 is used by an error correction block 47, making the needed correction.

However, such a embodiment has two kind of problems: 1) a detection problem; that is, it is not always possible to detect all the error events; and 2) a miscorrection problem; that is, sometimes the correction made by the post processor is wrong and therefore the resulting BER can be equal or higher than the output BER of the Viterbi detector 23.

In fact, if a single parity bit channel code is implemented, the error events, such as “+” or “−” (wherein in a sequence “ . . . 1 0 . . . ” is performed as “ . . . 0 1 . . . ”), are not detected because they do not modify the parity.

Error events, such “+” or “+−+”, are detectable because they modify the parity, but the post processor could confuse them, if the associated energy to the error events it is not sufficiently high to allow a suitable discrimination.

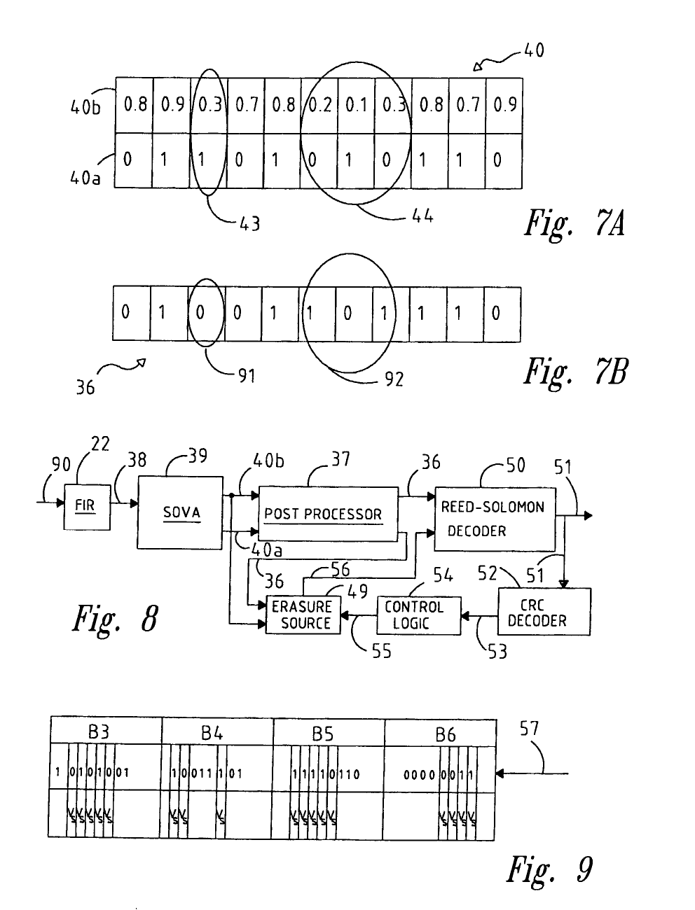

In FIG. 6 is shown a block diagram of a combination between a SOVA detector and a post processor that makes full use of the characteristics of a parity channel code according to the present invention.

Wherever possible, the same reference numbers of FIG. 5 are used in FIG. 6 and in the description to refer to the same or like parts.

The FIR 22 receives a signal 90 from the disk-head assembly 3 and said FIR 22 generates a discrete, equalized signal 38 that is input to a SOVA 39 and to the delay line 30.

The output 40 of the SOVA 39 is a stream of bits 40a and the associated reliability 40b.

In the specific embodiment the reliability of each bit is measured by a number comprised between zero, which is the lower reliability, and one, which is the higher reliability, as described hereinafter in FIG. 7a and FIG. 7b.

The outputs 40a and 40b of the SOVA 39 are filtered by means of the post processor 37, which includes an identical polynomial P(D) used for the equalization operation, and the group of filters 32, . . . , 35.

Even in this specific embodiment a target EPR4 is used, and therefore the polynomial 28 is:

P(D)=1+D−D²−D³ (2)

The polynomial 28 generates a new sequence 94 that represents the ideal samples generated by the FIR 22 if the transmission channel 12 is noiseless.

By means of the adder node 29, the output samples 94 are subtracted to real output samples of the FIR 22, and these are delayed by means of the delay line 30.

In such an embodiment, the SOVA 39 gives to the post processor 37 a list of possible error events, and moreover said SOVA 39 gives the position of said possible error events, highlighting opportunely each bit when the reliability value is lower than a predetermined threshold.

In this way, the post processor 37, taking into account the obtained syndrome and recalculating the parity of the bit stream, generated from the SOVA 39, produces in turn a list of possible error events without knowing the position of said possible error events.

As a consequence, the combination of the list generated by the SOVA 39 and by the post processor 37 reduces the number of undetectable error events, because, for example, the SOVA 39 can identify some errors that do not violate the parity and therefore they are undetectable by the post processor 37.

Moreover, this combination reduces the number of miscorrection, because sometimes it is possible to have a double identification of the error event.

Moreover, if the number of wrong bytes exceeds the correction capacity, the embodiments of the invention generates some erasures, combining again the data reliability of the SOVA 39 with that of the post processor 37.

In this way the deduced data 36 is used from the error correction block 47 to make the needed correction.

As FIG. 7a shows, the bit stream 40 generated by the SOVA 39 is divided into two streams 40b and 40a, wherein the stream 40b represents the reliability of the bit stream 40 and the stream 40a represents the bits of the bit stream 40.

In FIG. 7b the data 36 is depicted. There is a representation of the bit stream 40 after an operation of the error correction, made by the group of filters 32, . . . , 35.

In particularly, referring to the FIG. 7a, the bit stream 40 shows two error events 43 and 44, respectively, an error event 43 such as “−”, that is a bit 0 is interpreted as a bit 1, as shown in FIG. 7b, position 91, and an error event 44 such as “+, −, +”, that is a bit sequence 101 is interpreted as 010, as shown in FIG. 7b, position 92.

With embodiments of the prior art, such as with a bit parity correction technique or only with a SOVA detector, the two error events 43 and 44 should be not detectable.

In fact, in the case of a bit parity correction technique, the two error events 43 and 44 should be not detectable because the total parity of the bit stream 40 is maintained; and in the case of a SOVA detector, the two error events 43 and 44 should be not detectable because the SOVA gives only information about the reliability of the data.

When combining the SOVA 39 and the post processor 37, it has been found that integrating the capability of the SOVA 39, that is the capability of detecting the reliability of the data 38, and the capacity of the post processor 37, that is the capability of detecting specific error events, it is possible to correct the error events such as 43 and 44.

In fact, in the group of filters 32, . . . , 35, there will be a filter tuned to the single error event “+”, another filter tuned to the error event “+, −, +”, another filter tuned to the error event “+, −” and so on.

In this way, the filters tuned to the specific error events enable detection of the presence and the exact position of the error events in the bit stream 40, so to the error identification and correction block 47 generates an error free bit stream 48.

However, the group of filters 32, . . . , 35 of the post processor 37 can not identify correctly all the error events presenting on the magnetic recording channel of the mass storage system, because the list of the error events is limited due to obvious reasons.

In FIG. 8 another block diagram of a combination between a SOVA detector and a post processor according to another embodiment of the present invention is shown.

Wherever possible, the same reference numbers of FIG. 6 are used in FIG. 8 and in the description to refer to the same or like parts.

The FIR 22 receives the signal 90 from the disk-head assembly 3 and the FIR 22 generates a discrete, equalized signal 38 that is input to a SOVA 39. The output 40 of the SOVA 39 is a stream of bits 40a and the associated reliability 40b.

The outputs 40a and 40b of the SOVA 39 are filtered by means of the post processor 37 as described in heretofore in FIG. 6.

In such an embodiment, the SOVA 39 gives to the post processor 37 the bit stream 40a and the reliability 40b, whilst the post processor 37 generates the data 36 that inputs to a Reed-Solomon decoder 50 and to an erasure source 49.

The SOVA 39, moreover, gives the reliability 40b of the bit stream 40a to the erasure source 49, and the erasure source 49 produces a signal 56 that is input to said Reed-Solomon decoder 50.

The Reed-Solomon decoder 50 is able to detect the wrong bytes in the output 40 and to correct them. In fact the Reed-Solomon code is a code that adds to the transmitting data a few bytes of redundancy, so as with “2 t” bytes of redundancy it is possible to correct until “t” wrong bytes.

The output 51 of the Reed-Solomon decoder 50 is input in a Cyclic Redundancy Check (CRC) decoder 52, and in turn the output 53 of the CRC decoder 52 is input to a control logic 54. The output 55 of the control logic 54 is input to the erasure source 49.

In such an embodiment the combination of the SOVA 39 and of the post processor 37 enables implementation of another correction step by means of the Reed-Solomon detector 50.

In fact, if a data sector is organized as shown in the following table 2:

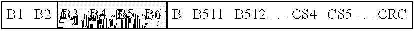

Sector length = 512 bytes
Num. check symbols = 6 bytes = 2t
Num. of correctable errors = t = 3

wherein a burst of four wrong symbols (B3, B4, B5 B6) is highlighted.

In this specific embodiment, the redundancy of the Reed-Solomon code “t=3” enables correction of a maximum of three errors. In this case, being the burst of symbols is equal to four, the burst prevents a correct reading of the sector.

However, the capability of correction of the Reed-Solomon code can increase until “2 t” bytes if the Reed-Solomon code knows the exact position of the wrong symbols.

As FIG. 8 shows, there is a series between the Reed-Solomon decoder 50 and the CRC decoder 52.

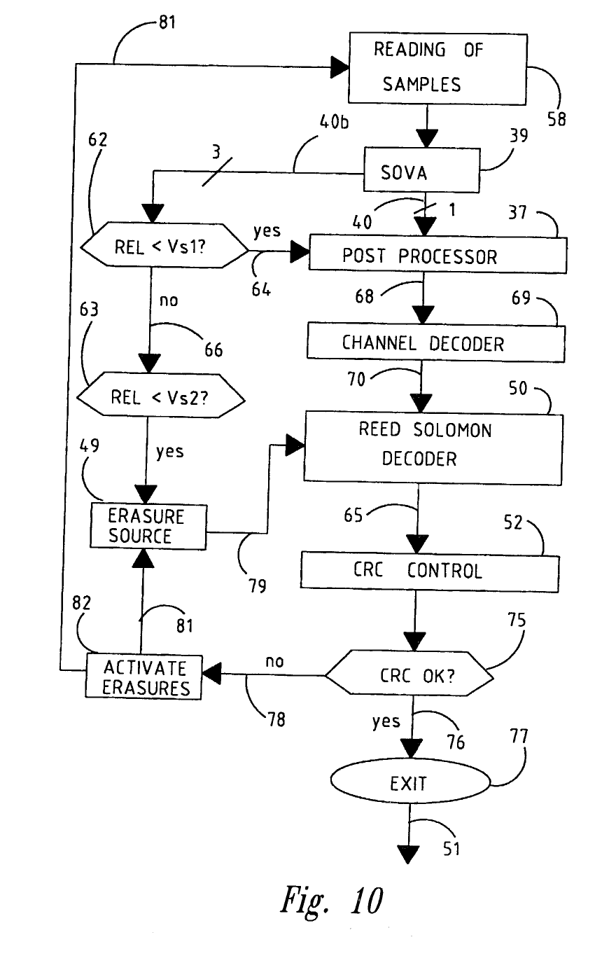

In this way, it is possible to implement a recovery procedure of the wrong sector by means of further redundancy, introduced by the CRC decoder 52, as described heretofore in FIG. 10.

FIG. 9 shows the burst B3, . . . , B6, the associated eight bits 57 and for some of the bits 57, belonging to the wrong bytes B3, . . . , B6, there is a particular value Vs of reliability.

For example, the byte B3 is made by the bit stream 10101001 and in particularly the bits one, two, three, four and five (that is 01010) have reliability lower than the threshold value Vs.

The flow chart described in FIG. 10 represents the way of operating of the inventive embodiment illustrated in FIG. 8.

In fact, after a first step 58 (“READING OF SAMPLES”), adapted for reading of the samples, disposed as depicted in table 2, there is a second step 39, implementing the Soft Output Viterbi Algorithm (“SOVA”), adapted to provide the bit stream 40 (that is the bit of the stream 40a and the associated reliability 40b of said bit stream 40a), having a resolution of one bit, to the post processor 37 and further the SOVA 39 provides the only reliability information 40b, having a resolution of three bits, to a first test block 62.

In fact, the reliability information 40b is compared with two prefixed threshold Vs1 and Vs2 by means of the two test blocks 62 and 63 (“REL<Vs1 ?”, and “REL<Vs2 ?”).

If the reliability information 40b is lower that the first threshold value Vs1 an opportune signal, path 64, is delivered to the post processor 37. This last uses the signal 64 to improve the detection.

If the reliability information 40b is higher that the first threshold value Vs1, path 66, the test block 63 is performed.

The test block 63 examines the reliability information 40b, and when this reliability information 40b is comprised between the two threshold values Vs1 and Vs2, then the test block 63 activates an erasure source 49 (“ERASURE SOURCE”).

The post processor 37, in function of the signal 64 and in function of the output 40 of the SOVA 39, generates a further bit stream 68 that is input to the channel decoder 69.

The channel decoder 69 takes this further bit stream 68 and attempts to reproduce the information sequence 58 into a new sequence 70.

The sequence 70 is input to a Reed-Solomon decoder 50, adapted to detect the wrong bytes in the output 70 and to correct them, providing a further bit stream 65.

The further bit stream 65, provided by the Reed-Solomon decoder 50, is subjected to a CRC control 52.

When the CRC control 52 is correct, path 76 of the test block 75 (“CRC OK ?”), the sequence of the operations is terminated, block 77 (“EXIT”), and therefore the output bit stream 51 is provided.

When the CRC 52 control is wrong, path 78 of the test block 75 (“CRC OK ?”), an opportune signal 81 is released from an erasure block 82 (“ACTIVATE ERASURES”), so as to activate said erasure source block 67 and to restart the sequence of the operations, that is block 58, until the outcome of the control CRC 52 is correct.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims and the equivalents thereof.

1. A method for detecting and correcting errors in a sequence of signals, the method comprising the steps of:
a) receiving said signals over a communication channel corrupted by noise;
b) transforming said signals into discrete signals equalized to a predetermined target function;
c) computing a bit stream and the associated reliability of said discrete signals;
d) postprocessing said bit stream and said reliability as a function of said discrete signals to detect specific error events;
e) making correction of said error events by filtering each single error event; and
f) generating an output bit stream.

2. The method of claim 1, the method modified in steps (d), (e) and (f) that are replaced by the following steps:
g) comparing the reliability associated with said bit stream with at least a prefixed value threshold;
h) generating a first signal when the comparison of step (g) is lower than said at least prefixed value threshold;
i) postprocessing said bit stream and the associated reliability as a function of the first signal, so as to provide a new bit stream;
j) adding bytes of redundancy to said new bit stream so as to provide a further bit stream;
k) verifying the consistency of said further bit stream;
l) when verifying step (k) is consistent, providing an output bit stream; and
m) when verifying step (k) is not consistent, repeating the steps from (g) to (m).

3. The method of claim 2, further comprising the steps of:
n) providing a second signal in the case of the outcome of the comparison of the step (g) is higher that said at least threshold value;
o) adding redundancy bytes to said new bit stream so as to provide a further bit stream in function of said second signal;
p) verifying the consistency of said further bit stream;
q) when verifying step (p) is consistent, providing an output bit stream;
r) when verifying step (p) is not consistent, repeating the steps from (g) to (k) of claim 2.

4. The method of claim 1, wherein said step (c) is calculated by a Soft Output Viterbi Algorithm.

5. The method of claim 1, wherein said step (e) is calculated by a group of filters, each one of which is tuned to a specific error event.

6. The method of claim 1, wherein said step (f) is calculated by a correction block.

7. The method of claim 2, wherein said step (d) and said step (i) are calculated by a post processor.

8. The method of claim 3, wherein said step (j) and said step (o) are calculated by a Reed-Solomon decoder.

9. The method of claim 3, wherein said step (e) and said step (p) are verified by means of a cyclic redundancy code.

10. An apparatus for detecting and correcting errors in a magnetic recording channel of a mass storage system, comprising: a Soft Output Viterbi Algorithm operable to receive a discrete equalized signal and to generate a bit stream and to associate a reliability with said bit stream; a delay line operable to receive said discrete equalized signal and to generate a delayed version of said discrete equalized signal; a post processor operable to receive said bit stream, said associated reliability, and said delay version of said discrete equalized signal, said post processor operable to generate a first signal; and an error correction block operable to receive said first signal and operable to generate an output bit stream.

11. The apparatus of claim 10, wherein said post processor comprises an equalization block operable to generate an equalized target of said bit stream and said associated reliability; an adder node operable to add said equalized target and said delayed version of said discrete equalized signal, said adder node operable to generate a second signal; a group of filters operable to receive said second signal, said group of filters operable to provide said second signal.

12. The apparatus for detecting and correcting errors in a magnetic recording channel according to claim 11, wherein said group of filters is tuned to a specific error event, present in said second signal.

13. The apparatus of claim 11, wherein said equalization block is implemented by a third order polynomial of the type P(D)=1+D−D²−D³.

14. The apparatus of claim 10, comprising an erasure source operable to receive said associated reliability of said discrete equalized signal and to receive a third signal, said erasure source operable to generate a fourth signal; a Reed-Solomon decoder operable to receive said third and fourth signal, said Reed-Solomon decoder operable to generate said output bit stream; a cyclic redundancy check decoder operable to receive said output bit stream, said cyclic redundancy check decoder operable to generate a fifth signal; and a control logic block operable to receive said fifth signal, said control logic block operable to generate a sixth signal, said sixth signal inputted to said erasure source.

15. A method for detecting and correcting errors in a magnetic reporting channel of a mass storage system, comprising: combining a Soft Output Viterbi Algorithm (SOVA) with a post processor, the SOVA configured to detect the reliability of a discrete, equalized signal, and the post processor configured to detect specific error events in the discrete, equalized signal to correct the error events and to generate an output bit stream.

16. An apparatus for detecting and correcting errors in a magnetic recording channel of a mass storage system, the apparatus comprising a processor configured with a Soft Output Viterbi Algorithm (SOVA), the SOVA configured to detect the reliability of a discrete, equalized signal; and a post processor configured to detect specific error events in the discrete, equalized signal, to correct the error events in the discrete, equalized signal, and to generate an output bit stream.

17. A method of detecting and correcting errors in a magnetic recording channel of a mass storage system, comprising:
transforming a sequence of signals into discrete signals equalized to a predetermined target function;
determining the reliability of the discrete signals;
comparing the reliability of the discrete signals with a prefixed value threshold;
generating a first signal when the comparison with the prefixed value threshold is lower than the prefixed value threshold;
processing the discrete signal and the reliability thereof as a function of the first signal to generate a bit stream;
adding bytes of redundancy to the bit stream to provide a further bit stream;
verifying the consistency of the further bit stream; and
when the consistency of the further bit stream is verified, generating an output bit stream, and when the consistency of the further bit stream is not verified, repeating the comparing, generating, postprocessing, adding, and verifying steps.

18. A method of detecting and correcting errors in a magnetic recording channel of a mass storage system, comprising:
transforming a sequence of signals into discrete signals equalized to a predetermined target function;
determining the reliability of the discrete signals;
comparing the reliability of the discrete signals with a prefixed value threshold;
generating a first signal when the comparison with the prefixed value threshold is lower than the prefixed value threshold;
processing the discrete signal and the reliability thereof as a function of the first signal to generate a bit stream;
adding bytes of redundancy to the bit stream to provide a further bit stream;
verifying the consistency of the further bit stream;
when the consistency of the further bit stream is verified, generating an output bit stream, and when the consistency of the further bit stream is not verified, repeating the comparing, generating, postprocessing, adding, and verifying steps;
providing a second signal when the comparison of the reliability with the prefixed value threshold is higher than the prefixed value threshold;
adding redundancy bytes to the bit stream so as to provide a second further bit stream as a function of the second signal;
verifying the consistency of the second further bit stream; and
when the consistency of the second further bit stream is verified, generating an output stream, and when the consistency is not verified, repeating the comparing, generating the first signal, processing, adding, and verifying the consistency steps.
